(19) United States
(12) Patent Application Publication
(10) Pub. No.: US 2025/0364056 A1
(43) Pub. Date: Nov. 27, 2025

(54) MEMORY DEVICE AND OPERATING METHOD THEREOF, AND MEMORY SYSTEM

(71) Applicant: YANGTZE MEMORY TECHNOLOGIES CO., LTD., Wuhan (CN)

(72) Inventors: Lu QIU, Wuhan (CN); JunYao ZHU, Wuhan (CN); PeiCheng CHEN, Wuhan (CN); Wei ZENG, Wuhan (CN); XueQing HUANG, Wuhan (CN)

(21) Appl. No.: 18/912,091

(22) Filed: Oct. 10, 2024

(30) Foreign Application Priority Data
May 21, 2024 (CN) 202410637459.6

(51) Int. Cl. G11C 16/26; G11C 16/08

(52) U.S. Cl. CPC G11C 16/26; G11C 16/08

(57) ABSTRACT

The present disclosure provides a memory device and an operating method, and a memory system thereof, the memory device includes a memory array, a peripheral circuit coupled to the memory array, a target word line coupled to memory cells in the memory array, and a first word line adjacent to the target word line; the peripheral circuit is configured to: in a pre-pass phase for performing a read operation on a memory cell coupled to the target word line, apply a first pass voltage to the first word line; in a first sub-phase of a first read phase after the pre-pass phase, reduce the voltage on the first word line from the first pass voltage to a first voltage; in a second sub-phase of the first read phase, increase the voltage on the first word line from the first voltage to a second pass voltage.

### CROSS-REFERENCE TO RELATED APPLICATIONS

This application claims priority to and the benefit of Chinese Patent Application No. 202410637459.6, filed on May 21, 2024, which is hereby incorporated by reference in its entirety.

### TECHNICAL FIELD

The present disclosure relates to the field of semiconductor technology, and in particular to a memory device and operating method, and a memory system thereof.

### BACKGROUND

A memory device is a storage device used to preserve information in modern information technology. As a typical non-volatile semiconductor memory, NAND (Not-And) memory has gradually become a mainstream product in the storage market due to its high storage density, controllable production cost, suitable programming and erasing speed. However, as people's requirements for storage devices continue to increase, there is still much room for improvement in memory devices and their systems.

### SUMMARY

Implementations of the present disclosure provide a memory device and operating method and a memory system thereof.

In a first aspect, an implementation of the present disclosure provides a memory device, wherein the memory device includes a memory array, a peripheral circuit coupled to the memory array, a target word line coupled to memory cells in the memory array, and a first word line adjacent to the target word line.

The peripheral circuit is configured to: in a pre-pass phase for performing a read operation on a memory cell coupled to the target word line, apply a first pass voltage to the first word line; in a first sub-phase of a first read phase after the pre-pass phase, reduce a voltage on the first word line from the first pass voltage to a first voltage; in a second sub-phase of the first read phase, increase the voltage on the first word line from the first voltage to a second pass voltage.

In an optional implementation, the peripheral circuit is further configured to: in the pre-pass phase, apply a third pass voltage to the target word line; in the first read phase, apply a first read voltage to the target word line; the first read voltage is less than the third pass voltage.

In an optional implementation, the peripheral circuit is further configured to: in a first sub-phase of the first read phase, reduce the voltage on the target word line from the third pass voltage to a second voltage; the second voltage is less than or equal to the first read voltage.

In an optional implementation, the peripheral circuit is further configured to: in a second read phase after the first read phase for performing the read operation on the memory cell coupled to the target word line, apply a second read voltage to the target word line; the second read voltage is less than the first read voltage.

In an optional implementation, the peripheral circuit is further configured to: in a first sub-phase of the second read phase, reduce the voltage on the first word line from the second pass voltage to a third voltage; in a second sub-phase of the second read phase, increase the voltage on the first word line from the third voltage to a fourth pass voltage.

In an optional implementation, the difference between the third pass voltage and the first read voltage is greater than the difference between the first read voltage and the second read voltage.

In an optional implementation, the difference between the first pass voltage and the first voltage is greater than or equal to the difference between the second pass voltage and the third voltage.

In an optional implementation, the first pass voltage is equal to the second pass voltage.

In an optional implementation, the peripheral circuit is further configured to: in a third sub-phase of the first read phase, apply the second pass voltage to the first word line, and perform a first data sensing operation on the memory cells coupled to the target word line; in a third sub-phase of the second read phase, apply the fourth pass voltage to the first word line, and perform a second data sensing operation on a portion of the memory cells coupled to the target word line; the threshold voltages of the portion of the memory cells are all less than the first read voltage.

In an optional implementation, the memory cell coupled to the target word line is configured to store N-bit data; the N is an integer greater than 2; and the peripheral circuit is specifically configured to: perform the read operation on the memory cell coupled to the target word line to read one bit of the N-bit data stored in the memory cell coupled to the target word line.

In an optional implementation, the memory device further includes a second word line adjacent to the target word line; the target word line is located between the first word line and the second word line; the peripheral circuit is further configured to: in the pre-pass phase, apply a fifth pass voltage to the second word line; in the first sub-phase of the first read phase, reduce the voltage on the second word line from the fifth pass voltage to a fourth voltage; in the second sub-phase of the first read phase, increase the voltage on the second word line from the fourth voltage to a sixth pass voltage.

In an optional implementation, the fifth pass voltage is equal to the first pass voltage; the fourth voltage is equal to the first voltage; and the sixth pass voltage is equal to the second pass voltage.

In an optional implementation, the memory device further includes a third word line; the first word line is located between the target word line and the third word line; the peripheral circuit is further configured to: when performing the read operation on the memory cell coupled to the target word line, apply a seventh pass voltage to the third word line; the seventh pass voltage is less than the second pass voltage.

In a second aspect, an implementation of the present disclosure provides a memory system including: at least one memory device of any one of the implementations described above; a controller coupled to at least one of the memory devices and configured to control the memory device.

In a third aspect, an implementation of the present disclosure provides an operating method for a memory device including: in a pre-pass phase for performing a read operation on a memory cell coupled to a target word line, applying a first pass voltage to a first word line adjacent to the target word line; in a first sub-phase of a first read phase after the pre-pass phase, reducing the voltage on the first word line from the first pass voltage to a first voltage; in a second sub-phase of the first read phase, increasing the voltage on the first word line from the first voltage to a second pass voltage.

In an optional implementation, the operating method for the memory device further includes: in the pre-pass phase, apply a third pass voltage to the target word line; in the first read phase, apply a first read voltage to the target word line; the first read voltage is less than the third pass voltage.

In an optional implementation, applying a first read voltage to the target word line in the first read phase includes: in a first sub-phase of the first read phase, reducing the voltage on the target word line from the third pass voltage to a second voltage; the second voltage is less than or equal to the first read voltage.

In an optional implementation, the operating method for the memory device further includes: in a second read phase after the first read phase for performing the read operation on the memory cell coupled to the target word line, applying a second read voltage to the target word line; the second read voltage is less than the first read voltage.

In an optional implementation, the operating method for the memory device further includes: in a first sub-phase of the second read phase, reducing the voltage on the first word line from the second pass voltage to a third voltage; in a second sub-phase of the second read phase, increasing the voltage on the first word line from the third voltage to a fourth pass voltage.

In an optional implementation, the difference between the third pass voltage and the first read voltage is greater than the difference between the first read voltage and the second read voltage.

In an optional implementation, the difference between the first pass voltage and the first voltage is greater than or equal to the difference between the second pass voltage and the third voltage.

In an optional implementation, the operating method for the memory device further includes: in a third sub-phase of the first read phase, applying the second pass voltage to the first word line, and performing a first data sensing operation on the memory cells coupled to the target word line; in a third sub-phase of the second read phase, applying the fourth pass voltage to the first word line, and performing a second data sensing operation on a portion of the memory cells coupled to the target word line; the threshold voltages of the portion of the memory cells are all less than the first read voltage.

In an optional implementation, the operating method for the memory device further includes: in the pre-pass phase, applying a fifth pass voltage to a second word line adjacent to the target word line; the target word line is located between the first word line and the second word line; in the first sub-phase of the first read phase, reducing the voltage on the second word line from the fifth pass voltage to a fourth voltage; in the second sub-phase of the first read phase, increasing the voltage on the second word line from the fourth voltage to a sixth pass voltage.

### BRIEF DESCRIPTION OF THE DRAWINGS

FIG. 1 is a schematic diagram of an example system with a memory system provided by an implementation of the present disclosure.

FIG. 2 is a schematic diagram of an example memory card with a memory system provided by an implementation of the present disclosure.

FIG. 3 is a schematic diagram of an example solid state drive with a memory system provided by an implementation of the present disclosure.

FIG. 4 is a schematic diagram of an example memory device including a peripheral circuit provided by an implementation of the present disclosure.

FIG. 5 is a schematic diagram of an example memory device including a memory array and peripheral circuits provided by an implementation of the present disclosure.

FIG. 6 is a schematic diagram 1 of threshold voltage distribution of memory cells coupled to a target word line provided by an implementation of the present disclosure.

FIG. 7 is a schematic diagram 2 of threshold voltage distribution of memory cells coupled to a target word line provided by an implementation of the present disclosure.

FIG. 8 is a schematic diagram 3 of threshold voltage distribution of memory cells coupled to a target word line provided by an implementation of the present disclosure.

FIG. 9 is a schematic diagram 4 of threshold voltage distribution of memory cells coupled to a target word line provided by an implementation of the present disclosure.

FIG. 10 is a schematic diagram 5 of threshold voltage distribution of memory cells coupled to a target word line provided by an implementation of the present disclosure.

FIG. 11 is a schematic diagram of a memory block where the target word line is located provided by an implementation of the present disclosure.

FIG. 12 is a voltage curve 1 for performing a read operation on a memory cell coupled to a target word line provided by an implementation of the present disclosure.

FIG. 13 is a voltage curve 2 for performing a read operation on a memory cell coupled to a target word line provided by an implementation of the present disclosure.

FIG. 14 is a voltage curve 3 for performing a read operation on a memory cell coupled to a target word line provided by an implementation of the present disclosure.

FIG. 15 is a schematic flowchart of an operating method for a memory device provided by an implementation of the present disclosure.

### DETAILED DESCRIPTION

Exemplary implementations of the present disclosure will be described in more detail below with reference to the accompanying drawings. Although exemplary implementations of the present disclosure are shown in the accompanying drawings, it is to be understood that the present disclosure may be implemented in various forms and should not be limited to the specific implementations set forth herein. Rather, these implementations are provided so that the present disclosure can be more thoroughly understood and the scope of the present disclosure can be fully conveyed to those skilled in the art.

In the following description, numerous specific details are given in order to provide a more thorough understanding of the present disclosure. However, it will be apparent to one skilled in the art that the present disclosure may be practiced without one or more of these details. In other examples, in order to avoid confusion with the present disclosure, some technical features known in the art are not described; for example, not all features of the actual implementation are described here, and well-known functions and structures are not described in detail.

In the appended drawings, like reference numerals refer to like elements throughout.

It is to be understood that the spatially relative terms such as “beneath”, “below”, “lower”, “under”, “above”, “on”, etc., may be used herein for ease of description to describe one element or feature's relationship to another element(s) or feature(s) as illustrated in the appended drawings. It will be understood that the spatially relative terms are intended to encompass different orientations of the device in use or operations in addition to the orientation depicted in the figures. For example, if the device in the appended drawings is turned over, an element or a feature described as “below” or “beneath” or “under” another element or feature would then be oriented “above” the other element or feature. Thus, exemplary terms “below” and “under” may encompass both directions of up and down. A device may be otherwise oriented (rotated 90 degrees or at other orientations) and the spatially descriptive terms used herein should be interpreted accordingly.

A term used herein is for the purpose of describing a particular implementation only and is not to be considered as limitation of the present disclosure. As used herein, the singular forms “a”, “an” and “said/the” are intended to include the plural forms as well, unless the context clearly dictates otherwise. It should also be understood that the terms “consists of” and/or “comprising”, when used in this description, identify the presence of stated features, integers, steps, operations, elements and/or parts, but do not exclude the presence or addition of one or more other features, integers, steps, operations, elements, parts and/or groups. As used herein, the term “and/or” includes any and all combinations of the associated listed items.

A memory system in an implementation of the present disclosure includes, but is not limited to, a memory system including a three-dimensional NAND memory, and for case of understanding, a memory system provided by the present disclosure will be described by taking a memory system including a three-dimensional NAND memory as an example.

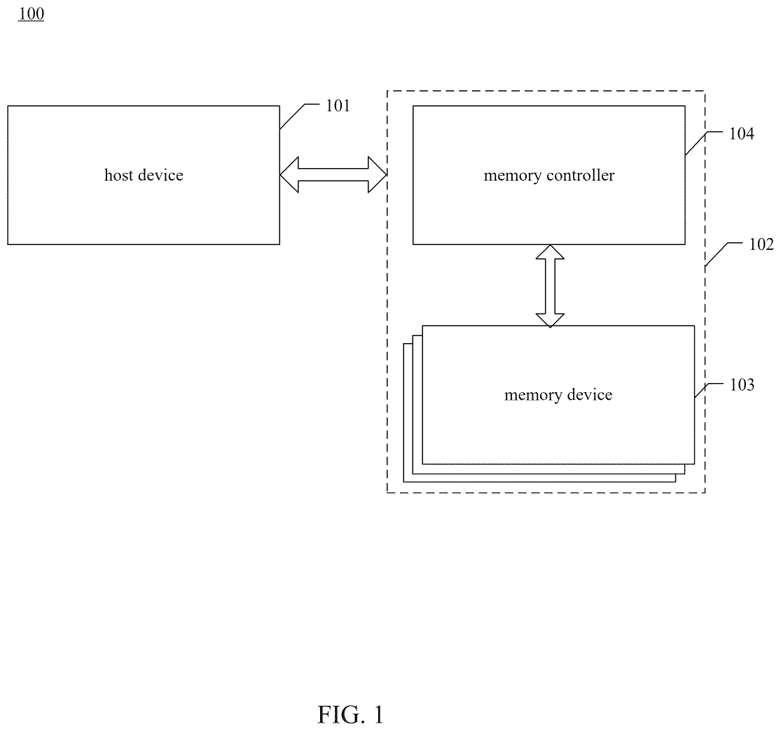

FIG. 1 is a schematic diagram of an example system with a memory system provided by an implementation of the present disclosure. In an implementation of the present disclosure, the system 100 may be a mobile phone, a desktop computer, a laptop computer, a tablet, a vehicle computer, a gaming console, a printer, a positioning device, a wearable electronic device, a smart sensor, a Virtual Reality (VR) device, an Augmented Reality (AR) device, or any other suitable electronic devices having a memory therein. As shown in in FIG. 1, the system 100 may include a host device 101 and a memory system 102, and the memory system 102 may include one or more memory devices 103 and a memory controller 104. The host device 101 may include a processor of an electronic device, e.g., a Central Processing Unit (CPU)) or a System on Chip (SoC), e.g., an Application Processor (AP). The host device 101 may be configured to send data to or receive data from the memory system 102.

In some implementations, the memory controller 104 is coupled to the memory device 103 and the host device 101 and is configured to control the memory device 103. The memory controller 104 may manage data stored in the memory device 103 and communicate with the host device 101. In some implementations, the memory controller 104 is designed to be used to operate in low duty cycle environments, e.g., to operate in Secure Digital Card, Compact Flash Card (CFC), Universal Serial Bus (USB) flash drive, or used to operate in other media for use in electronic devices such as personal computer, digital camera, mobile phone, etc. In some other implementations, the memory controller 104 is designed to be used to operate in high duty cycle environments, e.g., to operate in Solid State Drive or Embedded Multi Media Card (eMMC).

In some implementations, the memory controller 104 and one or more memory devices 103 may be integrated into various types of storage devices, e.g., the memory system 102 may be implemented and packaged into different types of terminal electronic products.

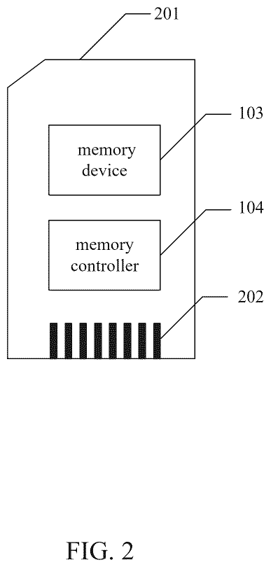

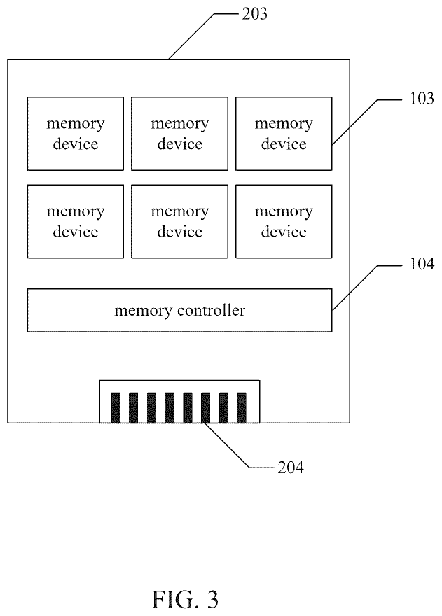

In an example as shown in FIG. 2, memory controller 104 and a single memory device 103 may be integrated into a memory card 201. The memory card 201 may be one of a Compact Flash Card, Smart Media Card (SMC), Memory Stick (MS), Multi-Media Card (MMC) (e.g., RS-MMC, MMCmicro, eMMC, etc.), a secure digital card (e.g., Mini SD card, Micro SD card, SDHC card, etc.), Universal Flash Storage card. The memory card 201 may further include a memory card connector 202 coupling the memory card 201 with a host device (e.g., the host device 101 in FIG. 1). In another example as shown in FIG. 3, the memory controller 104 and multiple memory devices 103 may be integrated into SSD203. SSD203 may further include an SSD connector 204 coupling the SSD203 with a host device (e.g., the host device 101 in FIG. 1). In some implementations, the storage capacity and/or operating speed of SSD203 is greater than the storage capacity and/or operating speed of memory card 201.

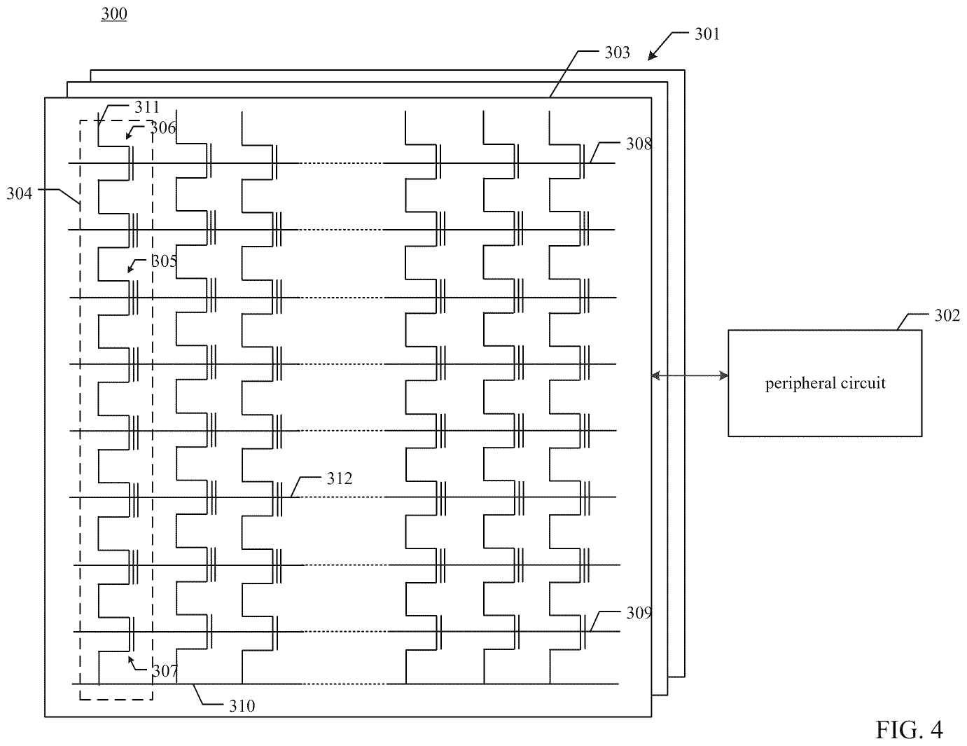

FIG. 4 is a circuit schematic diagram of an example memory device 300 including a peripheral circuit provided by an implementation of the present disclosure. Memory device 300 may be an example of memory device 103 in FIG. 1. The memory device 300 may include a memory array 301 and peripheral circuit 302 coupled to the memory array 301. Taking memory array 301 being a three-dimensional NAND memory array as an example for illustration, where memory cells 305 is a NAND memory cell, and memory cells 305 are provided in the form of an array of memory cell strings 304, each memory cell string 304 extending vertically over a substrate (not shown). In some implementations, each memory cell string 304 includes multiple memory cells 305 coupled in series and stacked vertically. Each memory cell 305 may retain a continuous analog value, e.g., voltage or charge, depending on the number of electrons trapped within the area of the memory cell 305. Each memory cell 305 may be a floating gate type memory cell including a floating gate transistor, or a charge trap type memory cell including a charge trap transistor.

In some implementations, each memory cell 305 is a Single Level Cell (SLC) that has two possible memory states and may thus store one bit of data. For example, a first memory state of “O” may correspond to a first voltage range, and a second memory state of “1” may correspond to a second voltage range. In some implementations, each memory cell 305 is a multi-level cell capable of storing more than a single bit of data in four or more memory states, e.g., a Multi-Level Cell (MLC) storing two bits per cell, a Triple Level Cell (TLC) storing three bits per cell, or a Quad-Level Cell (QLC) storing four bits per cell.

As shown in FIG. 4, each memory cell string 304 may include a Bottom Select Transistor (BST) 307 at its source terminal and a Top Select Transistor (TST) 306 at its drain terminal. The Bottom Select Transistor 307 and Top Select Transistor 306 may be configured to activate the selected memory cell string 304 during read operation and program operation. In some implementations, sources of the memory cell strings 304 in a same memory block 303 are coupled through a Common Source Line (CSL) 310. For example, all memory cell strings 304 in a same memory block 303 have an Array Common Source (ACS). According to some implementations, the top select transistor 306 of each memory cell string 304 is coupled to a corresponding Bit Line (BL) 311 from which data may be read or written via an output bus (not shown). In some implementations, each memory cell string 304 is configured to be selected or deselected through a select voltage (e.g., a voltage higher than the threshold voltage of the top select transistor 306) or a deselect voltage (e.g., OV) being applied to the Top Select Gate (TSG) of the corresponding top select transistor 306 via one or more Top Select Lines (TSL) 308 and/or a select voltage (e.g., a voltage higher than the threshold voltage of the bottom select transistor 307) or a deselect voltage (e.g., OV) being applied to the Bottom Select Gate (BSG) of the corresponding bottom select transistor 307 via one or more Bottom Select Lines (BSL) 309.

As shown in FIG. 4, the memory cell string 304 may be organized into multiple memory blocks 303, each of which may have a common source line 310. In some implementations, each memory block 303 is the basic data unit for an erase operation, e.g., all memory cells 305 on the same memory block 303 are erased simultaneously. To erase the memory cell 305 in the selected memory block, common source line 310 coupled to selected memory block and to unselected memory blocks in the same plane as selected memory block may be biased with an erase voltage. It is to be understood that, in some examples, crase operations may be performed at the half-memory block level, at the quarter-memory block level, or at a level with any suitable number of memory blocks or any suitable fraction of memory blocks. Memory cells 305 of adjacent memory cell strings 304 may be coupled through a word line 312 that selects which row of memory cells 305 is affected by read operation or program operation.

In some implementations, the peripheral circuit 302 may include any suitable analog, digital, and mixed-signal circuitry for implementing operation of the memory array 301 through applying a voltage signal and/or a current signal to and sensing voltage signal and/or current signal from each target memory cell 305 via bit line 311, word line 312, common source line 310, bottom select line 309, and top select line 308. The peripheral circuit 302 may include various types of peripheral circuits formed with metal-oxide-semiconductor technology.

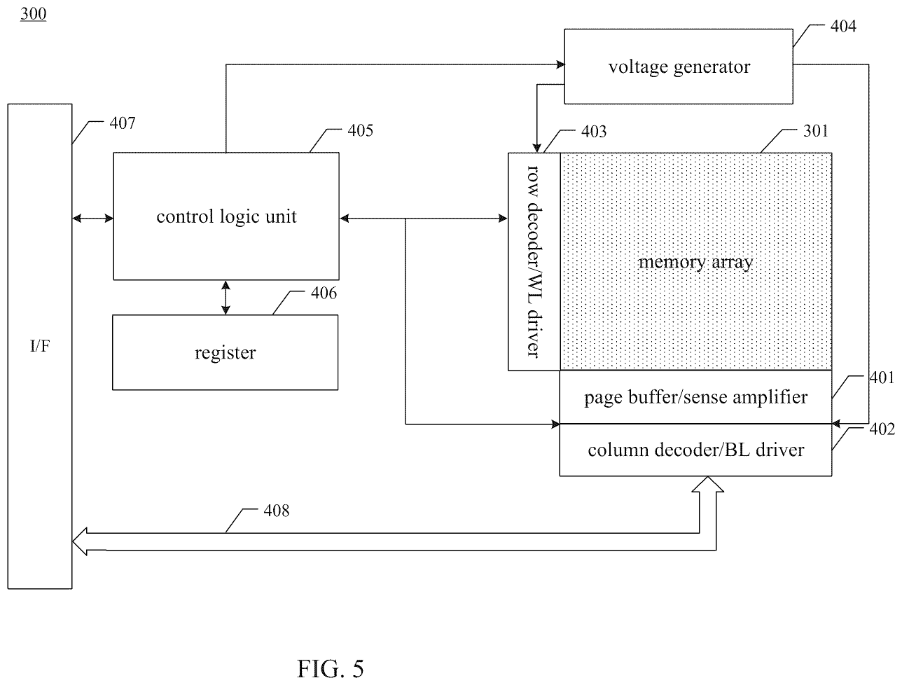

FIG. 5 illustrates some exemplary peripheral circuits, peripheral circuit 302 includes page buffer/sense amplifier 401, column decoder/bit line driver 402, row decoder/word line driver 403, voltage generator 404, control logic 405, register set 406, flash memory interface 407 and data bus 408. It is to be understood that in some examples, additional peripheral circuits not shown in FIG. 5 may also be included.

The page buffer/sense amplifier 401 may be configured to read data from and program (write) data to the memory array 301 according to control signals from the control logic 405. In an example, the page buffer/sense amplifier 401 may store one page of programming data (written data) to be programmed into the memory array 301. In another example, page buffer/sense amplifier 401 may perform a programming verify operation to ensure that data has been correctly programmed into memory cell coupled to selected word line. In yet another example, page buffer/sense amplifier 401 may also sense a low power signal from bit line representing a data bit stored in memory cell and amplify a small voltage swing to a recognizable logic level during a read operation. The column decoder/bit line driver 402 may be configured to be controlled by control logic 405 and to select one or more memory cell strings through applying a bit line voltage generated from voltage generator 404.

The row decoder/word line driver 403 may be configured to be controlled by control logic 405 and select/deselect memory block of memory array 301 and select/deselect word line of memory block. The row decoder/word line driver 403 may also be configured to drive word line with a word line voltage generated from the voltage generator 404. In some implementations, the row decoder/word line driver 403 may also select/deselect and drive the bottom select line and the top select line. As described in detail below, the row decoder/word line driver 403 is configured to perform programming operations on the memory cells coupled to the (one or more of) selected word line. The voltage generator 404 may be configured to be controlled by the control logic 405, and generate word line voltage (e.g., read voltage, programming voltage, pass voltage, local voltage, verify voltage, etc.), bit line voltage and source line voltage to be supplied to the memory array 301.

The control logic 405 may be coupled to each of the peripheral circuits described above and configured to control operations of each of the peripheral circuits. The register set 406 may be coupled to the control logic 405 and include status register, command register and address register for storing status information, command operation code (OP code) and command address for controlling operations of each of the peripheral circuits. The flash memory interface 407 may be coupled to control logic 405 and act as a control buffer to buffer and relay control commands received from a host device (not shown) to control logic 405 and to buffer and relay status information received from the control logic 405 to the memory controller. The flash memory interface 407 may also be coupled to column decoder/bit line driver 402 via data bus 408 and act as a data I/O interface and data buffer to buffer and relay data to/from memory array 301.

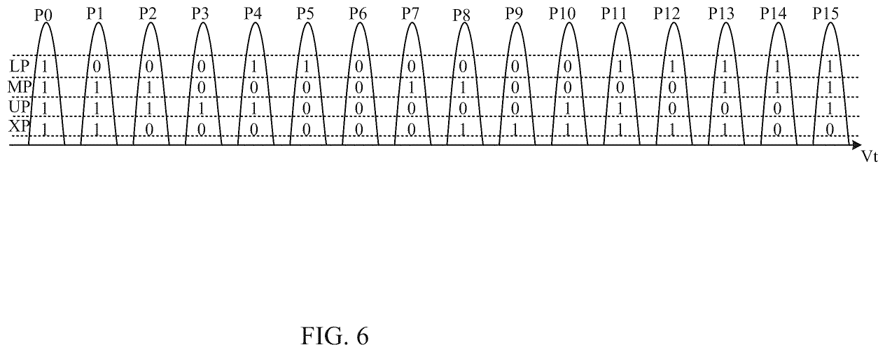

In some implementations, data stored in a multi-level memory cell may be read in a single page read approach. Taking a memory cell being a quad-level cell QLC as an example, FIG. 6 is a schematic diagram of the threshold voltage distribution of a memory cell coupled to a target word line, where each memory cell stores four bits of data, the threshold voltage of each memory cell is within a range of one of multiple threshold voltage distributions corresponding to the erase state P0 and fifteen program states P1 to P15, each threshold voltage distribution corresponding to a Gray Code, the data stored in the multiple memory cells may be logically divided into four pages based on a Gray code encoding method, including an upper page UP, a middle page MP, a lower page LP, and an extra page XP.

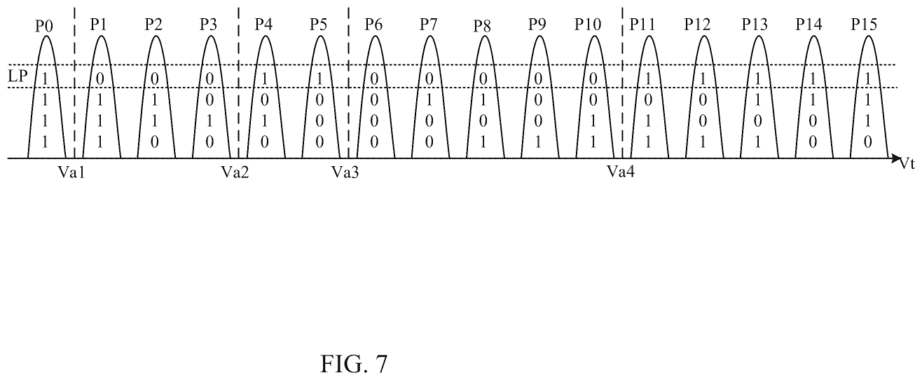

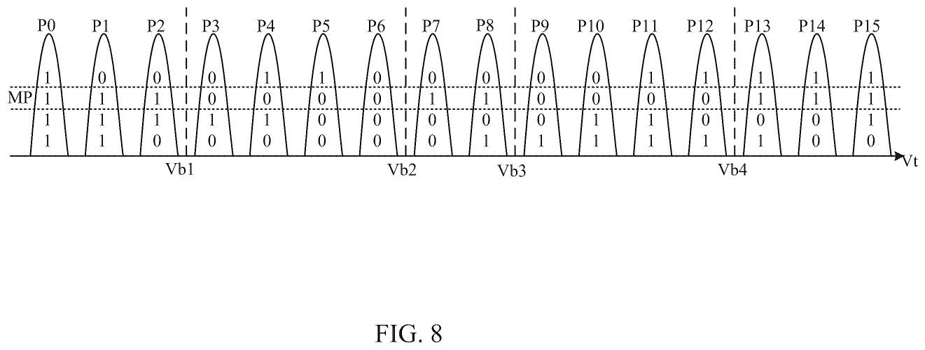

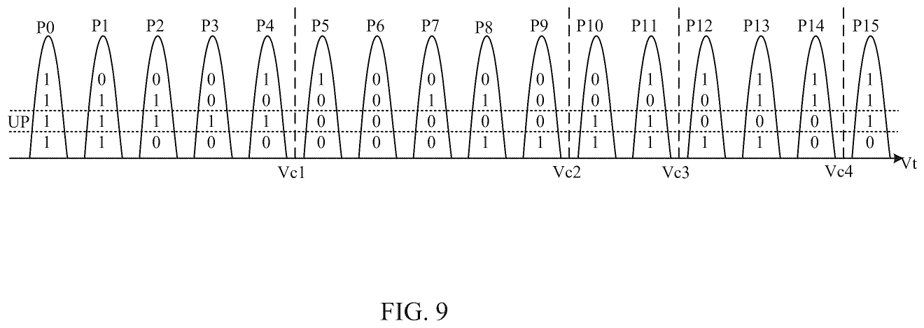

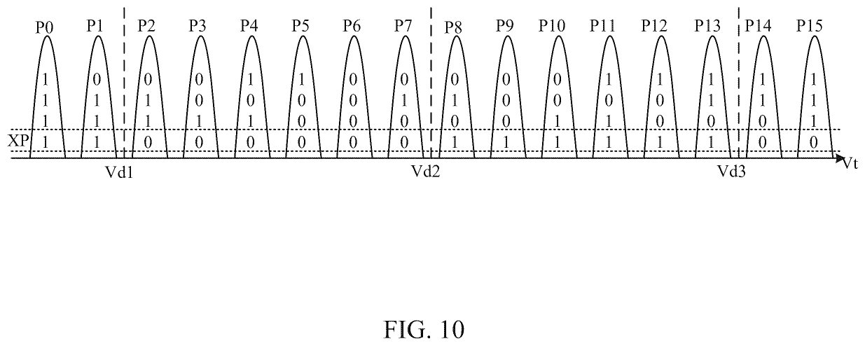

In some examples, as shown in FIG. 7, when the data of the lower page LP is read through single page read approach, read voltages Va1, Va2, Va3, and Va4 may be applied to the target word line. As shown in FIG. 8, when the data of the middle page MP is read through single page read approach, read voltages Vb1, Vb2, Vb3, and Vb4 may be applied to the target word line. As shown in FIG. 9, when the data of the upper page UP is read through single page read approach, read voltages Vc1, Vc2, Vc3, and Vc4 may be applied to the target word line. As shown in FIG. 10, when the data of the extra page XP is read through single page read approach, read voltages Vd1, Vd2, and Vd3 may be applied to the target word line.

It is to be noted that the Gray code encoding methods in FIGS. 6 to 10 are only examples, and when different encoding methods are used to write Gray codes, the number and magnitude of the read voltages required to be applied to read the data of each page are also different, and the present disclosure does not limit the specific encoding method of Gray codes.

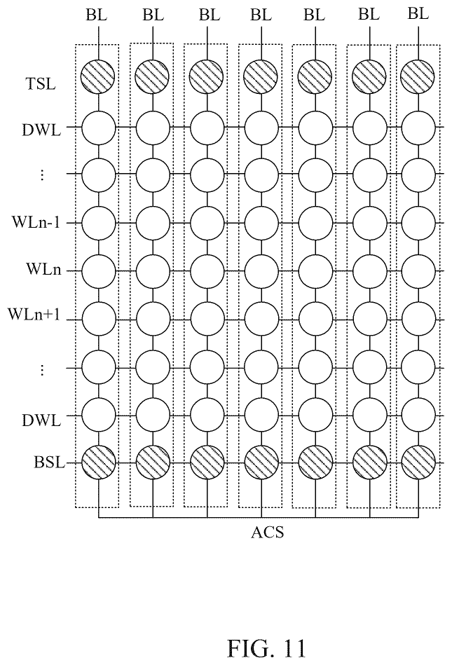

In some implementations, FIG. 11 is a schematic diagram of a memory block where a target word line is located, and in the process of performing a read operation on a memory cell coupled to a target word line WLn, it is required to precharge a bit line BL coupled to a memory cell string where a target memory cell of the read operation is located, apply a read voltage to the target word line WLn, and apply a pass voltage to word lines other than the target word line WLn so that all memory cells coupled to the word lines other than the target word line WLn are turned on, and apply a pass voltage to the top select line TSL and the bottom select line BSL to turn on both the top select transistor and the bottom select transistor, in this case, when the threshold voltage of the target memory cell is greater than the read voltage, the target memory cell is turned on, the memory cell string where the target memory cell is located is turned on, and the voltage on the bit line BL is discharged toward the common source ACS, When the threshold voltage of the target memory cell is less than or equal to the read voltage, the target memory cell remains in the off state, and the voltage on the bit line BL does not change. In this process, in conjunction with reference to FIG. 5, the page buffer/sense amplifier 401 coupled to the bit line BL may determine the result of the read according to the change of the voltage on the bit line BL.

During the read operation described above, read interference may be generated to the memory cells coupled to the word lines other than the target word line WLn. Specifically, the pass voltage applied to the word lines other than the target word line WLn needs to turn on all the memory cells coupled to that word line, so the pass voltage needs to be higher than the threshold voltage of the memory cell in the highest program state, when the number of read operations accumulates, the threshold voltage of the memory cell to which the pass voltage is applied multiple times may drift in the positive direction, especially for the memory cell in the crase state and the lower program state, its threshold voltage will drift more, which may lead to an increase in the error rate of the read operation.

However, reducing the pass voltage applied to the word line other than the target word line WLn will make the back-pattern effect more serious, causing the threshold voltage distribution of the memory cell to widen and the read window to decrease. Specifically, the back-pattern effect is mainly because the program state of the memory cell on the side of the memory cell coupled to the target word line WLn is different during the verification operation and the read operation. For example, when performing a program verification operation on a memory cell coupled to the target word line WLn, the memory cell coupled to the word line located between the target word line WLn and the common source ACS is in the erase state, while when performing a read operation on the memory cell coupled to the target word line WLn, the memory cell coupled to the word line located between the target word line WLn and the common source ACS is already in the program state, and when performing a read operation on a memory cell coupled to the target word line WLn, the channel resistance of the memory cell coupled to the word line located between the target word line WLn and the common source ACS increases significantly, which causes the threshold voltage of the memory cells coupled to the target word line WLn to increase, thereby causing a phenomenon in which the threshold voltage distribution is widened. In this case, if the pass voltage applied to word lines other than the target word line WLn is reduced, the back-pattern effect will be more serious.

Therefore, it is required to further optimize the voltage application approach during the read operation to reduce the read interference and improve the reliability of the memory device. To this end, the present disclosure proposes the following implementations.

The present disclosure provides a memory device, with reference to FIGS. 4, 5 and 11, the memory device includes a memory array 301, a peripheral circuit 302 coupled to the memory array 301, a target word line WLn coupled to memory cells in the memory array 301, and a first word line WLn+1 adjacent to the target word line WLn.

In some implementations, as shown in FIG. 11, the memory device further includes a second word line WLn−1 adjacent to the target word line WLn, and a third word line, the first word line WLn+1 is located between the target word line WLn and the third word line, or the second word line WLn−1 is located between the target word line WLn and the third word line. Here, the third word line is a word line not adjacent to the target word line WLn, specifically, the third word line may be a word line located between the first word line WLn+1 and the bottom select line BSL, or the third word line may be a word line located between the second word line WLn−1 and the top select line TSL.

It is to be noted that the target word line WLn may be any word line in the memory block, and when the target word line WLn is the word line closest to the top select line TSL, there is only the first word line WLn+1 adjacent to the target word line WLn, and the third word line is located between the first word line WLn+1 and the bottom select line BSL; and when the target word line WLn is the word line closest to the bottom select line BSL, there is only the second word line WLn−1 adjacent to the target word line WLn, and the third word line is located between the second word line WLn−1 and the top select line TSL. In the following, an example is taken in which the target word line WLn is located between the first word line WLn+1 and the second word line WLn−1 for illustration.

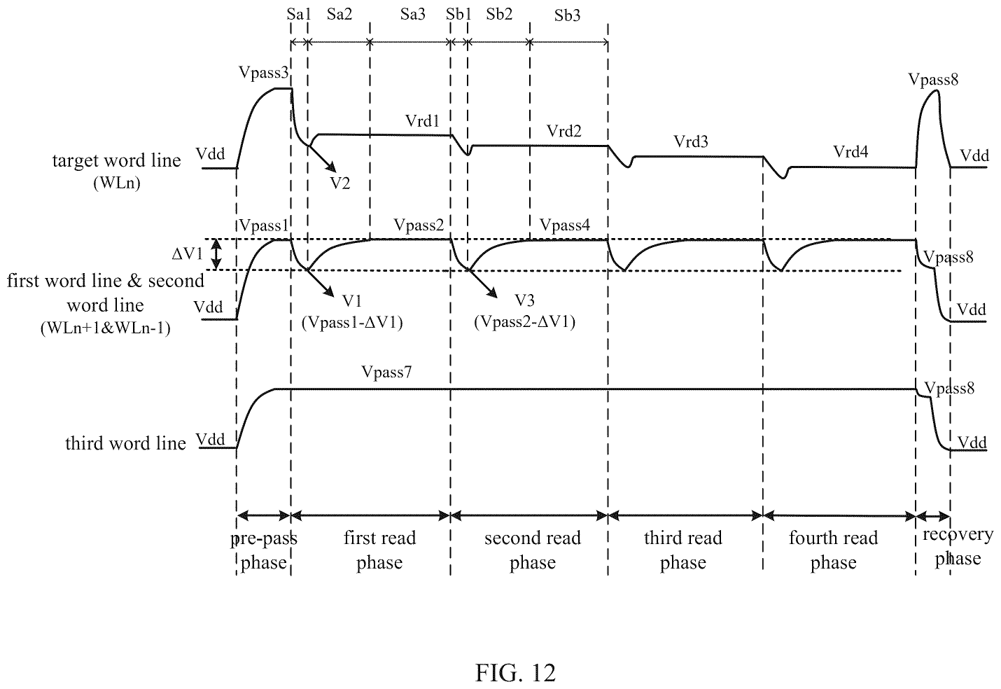

In some implementations, FIGS. 12, 13 and 14 are voltage curves for performing a read operation on a memory cell coupled to a target word line WLn provided by an implementation of the present disclosure. As shown in FIG. 12, the peripheral circuit 302 is configured to: in a pre-pass phase for performing a read operation on a memory cell coupled to the target word line WLn, apply a first pass voltage Vpass1 to the first word line WLn+1; in a first sub-phase Sa1 of a first read phase after the pre-pass phase, reduce the voltage on the first word line WLn+1 from the first pass voltage Vpass1 to a first voltage V1; in a second sub-phase Sa2 of the first read phase, increase the voltage on the first word line WLn+1 from the first voltage V1 to a second pass voltage Vpass2.

In some implementations, the peripheral circuit 302 is further configured to: in the pre-pass phase, apply a third pass voltage Vpass3 to the target word line WLn; in the first read phase, apply a first read voltage Vrd1 to the target word line WLn; the first read voltage Vrd1 is less than the third pass voltage Vpass3.

In the implementation of the present disclosure, the read operation includes a pre-pass phase, and the peripheral circuit 302 may be configured to apply a pass voltage to all word lines in the pre-pass phase to turn on all memory cells, apply a pass voltage to the bottom select line BSL and the top select line TSL to turn on the bottom select transistor and the top select transistor, and apply a ground voltage to the common source ACS so that each channel may be coupled to the common source ACS, the potential remaining in the channel in the previous operation may be cleared in the pre-pass phase, thereby reducing the negative impact of the residual potential in the channel on the read operation.

In some implementations, in the first read phase after the pre-pass phase, the peripheral circuit 302 may be configured to apply a first read voltage Vrd1 to the target word line WLn, and the first read voltage Vrd1 is less than the third pass voltage Vpass3, therefore, in the first sub-phase Sa1 of the first read phase, the voltage on the target word line WLn undergoes a drop process. Specifically, the peripheral circuit 302 is further configured to: in the first sub-phase Sa1 of the first read phase, reduce the voltage on the target word line WLn from the third pass voltage Vpass3 to the second voltage V2; the second voltage V2 is less than or equal to the first read voltage Vrd1. Here, the voltage applied to the target word line WLn may be constant as the first read voltage Vrd1, and when the voltage on the target word line WLn is over-discharged, the voltage on the target word line WLn first drops to the second voltage V2 and then rises from the second voltage V2 to the first read voltage Vrd1.

In some implementations, in the first sub-phase Sa1 of the first read phase, the peripheral circuit 302 may be configured to reduce the voltage on the first word line WLn+1 from the first pass voltage Vpass1 to the first voltage V1, for example, the voltage on the first word line WLn+1 May be reduced synchronously with the voltage on the target word line WLn, therefore, the voltage drop rate on the target word line WLn may be accelerated through utilizing the coupling effect between the first word line WLn+1 and the target word line WLn, thereby shortening the time of the first sub-phase Sa1 and improving the efficiency of the read operation.

In some implementations, in the second sub-phase Sa2 of the first read phase, the peripheral circuit 302 may be configured to: increase the voltage on the first word line WLn+1 from the first voltage V1 to the second pass voltage Vpass2. During this process, the voltage on the target word line WLn may rise from the second voltage V2 to the first read voltage Vrd1, and stabilize at the first read voltage Vrd1.

In some specific examples, the second pass voltage Vpass2 may be equal to the first pass voltage Vpass1.

It is to be noted that, in the implementation of the present disclosure, taking the case that the drop phase of the voltage on the target word line WLn completely coincides with the drop phase of the voltage on the first word line WLn+1 as an example, while in other implementations, the drop phase of the voltage on the target word line WLn may partially coincide with the drop phase of the voltage on the first word line WLn+1, e.g., before the second sub-phase Sa2, the voltage on the target word line WLn may have risen to the first read voltage Vrd1, which is not limited in the present disclosure.

In some implementations, in the third sub-phase Sa3 of the first read phase, the peripheral circuit 302 may be configured to: apply the second pass voltage Vpass2 to the first word line WLn+1, and perform a first data sensing operation on the memory cells coupled to the target word line WLn, e.g., the voltage change on the bit line BL is sensed by the page buffer/sense amplifier 401 coupled to the bit line BL.

In an implementation of the present disclosure, the first read phase includes a first sub-phase Sa1, a second sub-phase Sa2 and a third sub-phase Sa3, wherein the first sub-phase Sa1 and the second sub-phase Sa2 are voltage establishment phases, and the third sub-phase Sa3 is a data sensing phase, and before the third sub-phase Sa3, the voltage on the target word line WLn needs to be stabilized at the first read voltage Vrd1, and the voltage on the first word line WLn+1 needs to be stabilized at the second pass voltage Vpass2 to ensure the accuracy of data sensing. In the first sub-phase Sa1 and the second sub-phase Sa2, the time for which the voltage on the first word line WLn+1 is maintained at a higher pass voltage may be shortened by first dropping the voltage on the first word line WLn+1 to the first voltage V1 and then rising to the second pass voltage Vpass2, thereby reducing the read interference caused to the memory cells coupled to the first word line WLn+1.

In some implementations, with continued reference to FIG. 12, the peripheral circuit 302 is further configured to: in a second read phase after the first read phase, apply a second read voltage Vrd2 to the target word line WLn; the second read voltage Vrd2 is less than the first read voltage Vrd1; in a third read phase after the second read phase, apply a third read voltage Vrd3 to the target word line WLn, and the third read voltage Vrd3 is less than the second read voltage Vrd2; in a fourth read phase after the third read phase, apply a fourth read voltage Vrd4 to the target word line WLn, and the fourth read voltage Vrd4 is less than the third read voltage Vrd3.

In some implementations, the memory cell coupled to the target word line WLn is configured to store N-bit data; the N is an integer greater than 2; and the peripheral circuit 302 is specifically configured to: perform the read operation on the memory cell coupled to the target word line WLn to read one bit of the N-bit data stored in the memory cell coupled to the target word line WLn. For example, the read operation including multiple read phases may be a read operation for one page of data among N pages of data stored in the memory cell coupled to the target word line WLn. Below, the read operation is described by taking the memory cell coupled to the target word line being configured to store four bits of data as an example.

In some implementations, referring to FIGS. 7 and 12, the read operation performed on the memory cell coupled to the target word line WLn is a read operation for reading the lower page LP data, the first read voltage Vrd1 may be equal to Va4 in FIG. 7, the second read voltage Vrd2 may be equal to Va3 in FIG. 7, the third read voltage Vrd3 may be equal to Va2 in FIG. 7, and the fourth read voltage Vrd4 may be equal to Va1 in FIG. 7.

In some implementations, referring to FIGS. 8 and 12, the read operation performed on the memory cell coupled to the target word line WLn is a read operation for reading the middle page MP data, the first read voltage Vrd1 may be equal to Vb4 in FIG. 8, the second read voltage Vrd2 may be equal to Vb3 in FIG. 8, the third read voltage Vrd3 may be equal to Vb2 in FIG. 8, and the fourth read voltage Vrd4 may be equal to Vb1 in FIG. 8.

In some implementations, referring to FIGS. 9 and 12, the read operation performed on the memory cell coupled to the target word line WLn is a read operation for reading the upper page UP data, the first read voltage Vrd1 may be equal to Vc4 in FIG. 9, the second read voltage Vrd2 may be equal to Vc3 in FIG. 9, the third read voltage Vrd3 may be equal to Vc2 in FIG. 9, and the fourth read voltage Vrd4 may be equal to Vc1 in FIG. 9.

In some implementations, referring to FIG. 10, the read operation performed on the memory cells coupled to the target word line WLn is a read operation of reading the extra page XP data, and the read operation may include only three read phases, the read voltages of the three read phases may be respectively equal to Vd3, Vd2 and Vd1 in FIG. 10.

In the implementation of the present disclosure, the peripheral circuit 302 is configured to apply a successively decreasing read voltage to the target word line WLn, and compared with a read operation in which a successively increasing read voltage is applied to the target word line, the time for the voltage on the target word line WLn to drop from the first pass voltage Vpass1 to the first read voltage Vrd1 in the first read phase may be shortened, thereby improving the efficiency of the read operation.

In some implementations, with continued reference to FIG. 12, the peripheral circuit 302 is further configured to: in a first sub-phase Sb1 of the second read phase, reducing the voltage on the first word line WLn+1 from the second pass voltage Vpass2 to a third voltage V3; in a second sub-phase Sb2 of the second read phase, increasing the voltage on the first word line WLn+1 from the third voltage V3 to a fourth pass voltage Vpass4; in the third sub-phase Sb3 of the second read phase, applying the fourth pass voltage Vpass4 to the first word line WLn+1, and performing a second data sensing operation on a portion of the memory cells coupled to the target word line WLn. In some implementations, the threshold voltages of the portion of the memory cells are all less than the first read voltage Vrd1, e.g., the memory cells turned on in the first read phase.

In some implementations, the fourth pass voltage Vpass4 may be equal to the second pass voltage Vpass2.

In some implementations, the peripheral circuit 302 is further configured to: in the third read phase and the fourth read phase, apply a voltage to the first word line WLn+1 in a manner similar to that in the second read phase.

In the implementation of the present disclosure, the peripheral circuit 302 may be configured to: in the first sub-phase of each read phase, cause the voltage on the first word line WLn+1 to drop to a voltage lower than the pass voltage; in the second sub-phase, cause the voltage on the first word line WLn+1 to rise to the pass voltage; and in the third sub-phase, continue to apply the pass voltage to the first word line WLn+1, thereby shortening the time that the first word line WLn+1 is at a higher pass voltage during the entire read operation without affecting the accuracy of data sensing, thereby reducing the read interference caused by the read operation to the memory cells coupled to the first word line WLn+1.

In some implementations, referring to FIG. 12, the peripheral circuit 302 is further configured to: in the pre-pass phase, apply a fifth pass voltage to the second word line WLn−1, here the fifth pass voltage may be equal to the first pass voltage Vpass1; in the first sub-phase Sa1 of the first read phase, reduce the voltage on the second word line WLn−1 from the fifth pass voltage to the fourth voltage, here the fourth voltage may be equal to the first voltage V1; in the second sub-phase Sa2 of the first read phase, increase the voltage on the second word line WLn−1 from the fourth voltage to the sixth pass voltage, here the sixth pass voltage may be equal to the second pass voltage Vpass2.

In the implementation of the present disclosure, the peripheral circuit 302 may be configured to apply a voltage the same as the voltage applied to the first word line WLn+1 to the second word line WLn−1 adjacent to the target word line WLn when performing a read operation on a memory cell coupled to the target word line WLn, e.g., the voltage curve of the voltage on the first word line WLn+1 may be the same as the voltage curve of the voltage on the second word line WLn−1. Thus, the time during which the first word line WLn+1 and the second word line WLn−1 are at a higher pass voltage in the read operation may be shortened at the same time, thereby reducing the read interference caused by the read operation to the memory cells coupled to the first word line WLn+1 and the memory cells coupled to the second word line WLn−1.

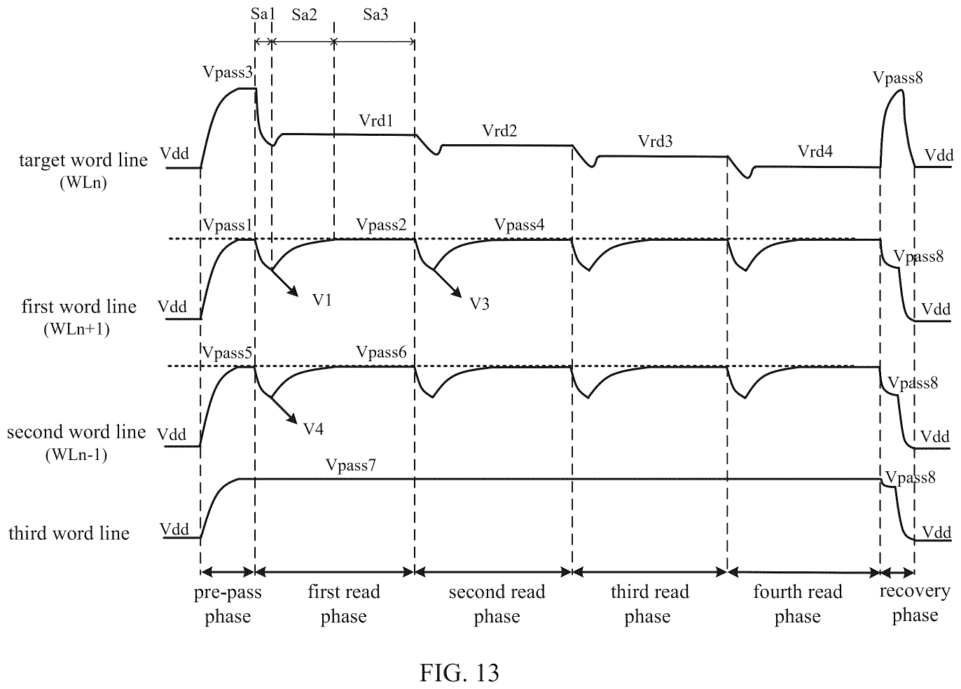

In some implementations, referring to FIG. 13, the peripheral circuit 302 is further configured to: in the pre-pass phase, apply a fifth pass voltage Vpass5 to the second word line WLn−1, here the fifth pass voltage Vpass5 may not be equal to the first pass voltage Vpass1; in the first sub-phase Sa1 of the first read phase, reduce the voltage on the second word line WLn−1 from the fifth pass voltage Vpass5 to the fourth voltage V4, here the fourth voltage V4 may not be equal to the first voltage V1; in the second sub-phase Sa2 of the first read phase, increase the voltage on the second word line WLn−1 from the fourth voltage V4 to the sixth pass voltage Vpass6, here the sixth pass voltage Vpass6 may not be equal to the second pass voltage Vpass2.

In the implementation of the present disclosure, the peripheral circuit 302 may be configured to apply a voltage different from the voltage applied to the first word line WLn+1 to the second word line WLn−1 adjacent to the target word line WLn when performing a read operation on a memory cell coupled to the target word line WLn.

In some implementations, the relative magnitudes of the voltages applied to the first word line WLn+1 and the second word line WLn−1 may be determined based on the order of the program operation. For example, when the program sequence is from the word line adjacent to the bit line BL to the word line adjacent to the common source ACS, the voltage applied to the first word line WLn+1 may be greater than the voltage applied to the second word line WLn−1, for example, the first pass voltage Vpass1 may be greater than the fifth pass voltage Vpass5, the first voltage V1 may be greater than the fourth voltage V4, and the second pass voltage Vpass2 may be greater than the sixth pass voltage Vpass6. On the contrary, when the program sequence is from the word line adjacent to the common source ACS to the word line adjacent to the bit line BL, the voltage applied to the first word line WLn+1 may be less than the voltage applied to the second word line WLn−1. Therefore, the read interference generated to the memory cell coupled to the word line adjacent to the target word line WLn may be reduced while alleviating the back model effect.

In some implementations, referring to FIGS. 12 and 13, the peripheral circuit 302 is further configured to: when performing the read operation on the memory cell coupled to the target word line WLn, apply a seventh pass voltage Vpass7 to the third word line; the seventh pass voltage Vpass7 is less than the second pass voltage Vpass2.

In the implementation of the present disclosure, the peripheral circuit 302 may be configured to apply a lower pass voltage to word lines not adjacent to the target word line WLn. It may be understood that when a read operation is performed on a target word line WLn, the read voltage applied to the target word line WLn is lower than the voltage applied to word lines other than the target word line WLn, which will cause the channel potential at the boundary region between the channel corresponding to the target word line WLn and the channel corresponding to the first word line WLn+1, as well as the channel potential at the boundary region between the channel corresponding to the target word line WLn and the channel corresponding to the second word line WLn−1 to be lower than the channel potential in other regions, thus may cause more serious read interference, therefore, for word lines not adjacent to the target word line WLn, the pass voltage applied thereto may be relatively small, while for word lines adjacent to the target word line WLn, the pass voltage applied thereto may be relatively large, thereby raising the channel potential and reducing read interference. Meanwhile, the read interference caused by the application of the pass voltage on the word line not adjacent to the target word line WLn may be reduced.

In some implementations, referring to FIG. 12, both the difference between the first pass voltage Vpass1 applied to the first word line WLn+1 and the first voltage V1 and the difference between the second pass voltage Vpass2 and the third voltage V3 may be AV1.

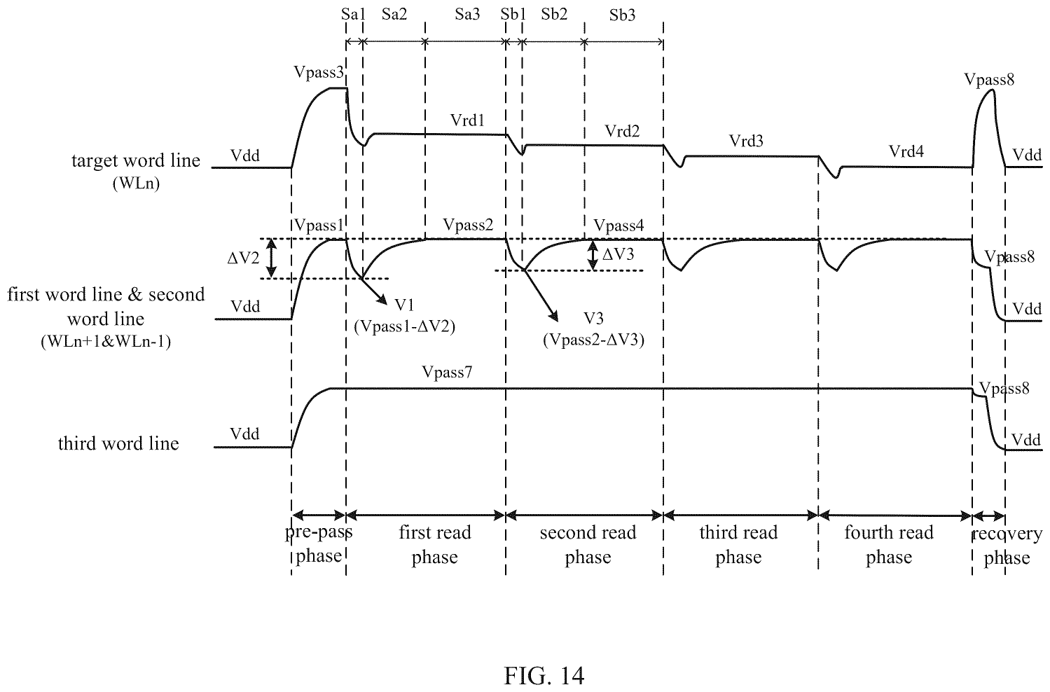

In some implementations, referring to FIG. 14, the difference between the third pass voltage Vpass3 applied to the target word line WLn and the first read voltage Vrd1 is greater than the difference between the first read voltage Vrd1 and the second read voltage Vrd2; the difference ΔV2 between the first pass voltage Vpass1 applied to the first word line WLn+1 and the first voltage V1 is greater than the difference ΔV3 between the second pass voltage Vpass2 and the third voltage V3. In this case, the rate at which the voltage on the target word line WLn drops from the third pass voltage Vpass3 to a voltage close to the first read voltage Vrd1 may be further increased, thereby further improving the efficiency of the read operation.

In the implementation of the present disclosure, in the first sub-phase of each read phase, the degree of drop in the voltage on the word line adjacent to the target word line may be proportional to the degree of drop in the voltage on the target word line, thereby further shortening the time of the voltage establishment phase and improving the efficiency of the read operation.

In some implementations, the peripheral circuit 302 is also configured to: in the recovery phase after the read phase, restore the memory cell strings to the state before the read operation. In some implementations, referring to FIGS. 12, 13 and 14, the peripheral circuit 302 may be configured to increase the voltage on the target word line WLn from the fourth read voltage Vrd4 to the eighth pass voltage Vpass8, and decrease the voltage on the word lines other than the target word line WLn to the eighth pass voltage Vpass8 during the recovery phase. During this process, the bottom select transistors and the top select transistors are still in the state of being turned on, and the memory cell strings are all turned on, thereby clearing the residual potential in the channel. Then, the voltage on all word lines may be reduced from the eighth pass voltage Vpass8 to the power supply voltage Vdd, and the voltage on the bottom select line BSL and the top select line TSL may be reduced to the ground voltage, thereby turning off all memory cells and bottom select transistors and top select transistors, and restoring the memory cell strings to the state before the read operation.

In the implementation of the present disclosure, the peripheral circuit is configured to: in a first sub-phase of each read phase for performing a read operation on a memory cell coupled to the target word line, reduce a voltage on a word line adjacent to the target word line from a higher pass voltage to a lower voltage; in a second sub-phase, increase the voltage on the word line adjacent to the target word line from a lower voltage to a higher pass voltage; and in a third sub-phase, apply a higher pass voltage to the word line adjacent to the target word line, and perform a data sensing operation on memory cells coupled to the target word line. In one aspect, in the first sub-phase, the voltage on the target word line and the voltage on the word line adjacent to the target word line may be synchronously decreased, so that the decreasing rate of the voltage on the target word line may be increased through utilizing the coupling effect between adjacent word lines, thereby improving the efficiency of the read operation; in another aspect, before the data sensing operation is performed, the voltage on the word line adjacent to the target word line is lower than the pass voltage, therefore, the time during which the voltage on the word line adjacent to the target word line is at a higher pass voltage may be shortened, thereby reducing read interference to memory cells coupled to the word line adjacent to the target word line, and improving the reliability of the memory device.

The present disclosure further provides a memory system, the memory system includes: at least one memory device of any one of the implementations described above; a controller coupled to at least one of the memory devices and configured to control the memory device. The specific composition and functional implementation of the memory system may be referred to the description of FIGS. 1 to 5 in the previous text, and for the sake of brevity, will not be repeated here.

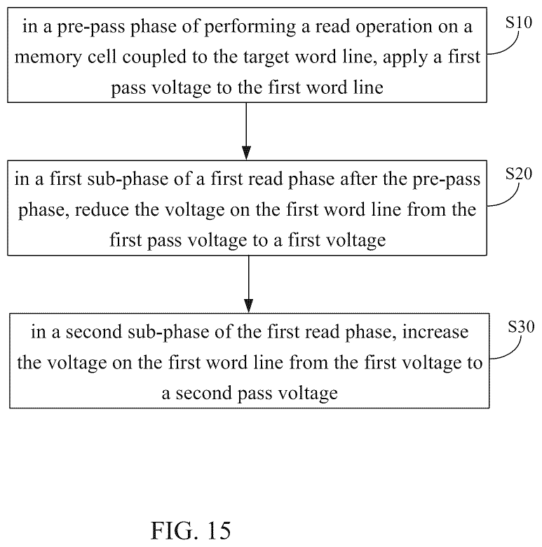

The present disclosure further provides an operating method for a memory device, FIG. 15 is a schematic flowchart of an operating method for a memory device provided by an implementation of the present disclosure, as shown in FIG. 15, the operating method for a memory includes following steps.

Step S10: in a pre-pass phase for performing a read operation on a memory cell coupled to the target word line, apply a first pass voltage to the first word line.

Step S20: in a first sub-phase of a first read phase after the pre-pass phase, reduce the voltage on the first word line from the first pass voltage to a first voltage.

Step S30: in a second sub-phase of the first read phase, increase the voltage on the first word line from the first voltage to a second pass voltage.

In some implementations, referring to FIGS. 12 and 15, the process of performing step S10 may include: in a pre-pass phase for performing a read operation on a memory cell coupled to the target word line WLn, apply a first pass voltage Vpass1 to the first word line WLn+1; the process of performing step S20 may include: in a first sub-phase Sa1 of a first read phase after the pre-pass phase, reducing the voltage on the first word line WLn+1 from a first pass voltage Vpass1 to a first voltage V1; the process of performing step S30 may include: in the second sub-phase Sa2 of the first read phase, increasing the voltage on the first word line WLn+1 from the first voltage V1 to the second pass voltage Vpass2.

In some implementations, referring to FIG. 12, the operating method for a memory device further includes: in the pre-pass phase, applying a third pass voltage Vpass3 to the target word line WLn; in the first read phase, applying a first read voltage Vrd1 to the target word line WLn; the first read voltage Vrd1 is less than the third pass voltage Vpass3.

In some implementations, referring to FIG. 12, in the first read phase, applying a first read voltage Vrd1 to the target word line WLn includes: in the first sub-phase Sa1 of the first read phase, reduce the voltage on the target word line WLn from the third pass voltage Vpass3 to the second voltage V2; the second voltage V2 is less than or equal to the first read voltage Vrd1.

In some implementations, referring to FIG. 12, the operating method for a memory device further includes: in a second read phase after the first read phase for performing the read operation on the memory cell coupled to the target word line WLn, applying a second read voltage Vrd2 to the target word line WLn; the second read voltage Vrd2 is less than the first read voltage Vrd1.

In some implementations, referring to FIG. 12, the operating method for a memory device further includes: in a first sub-phase Sb1 of the second read phase, reducing the voltage on the first word line WLn+1 from the second pass voltage Vpass2 to a third voltage V3; in a second sub-phase Sb2 of the second read phase, increasing the voltage on the first word line WLn+1 from the third voltage V3 to a fourth pass voltage Vpass4.

In some implementations, in conjunction with referring to FIGS. 12 and 14, the difference between the third pass voltage Vpass3 and the first read voltage Vrd1 is greater than the difference between the first read voltage Vrd1 and the second read voltage Vrd2; the difference between the first pass voltage Vpass1 and the first voltage V1 is greater than or equal to the difference between the second pass voltage Vpass2 and the third voltage V3.

In some implementations, referring back to FIG. 12, the operating method for a memory device further includes: in the third sub-phase Sa3 of the first read phase, applying the second pass voltage Vpass2 to the first word line WLn+1, and performing a first data sensing operation on the memory cells coupled to the target word line WLn; in the third sub-phase Sb3 of the second read phase, applying the fourth pass voltage Vpass4 to the first word line WLn+1, and performing a second data sensing operation on a portion of the memory cells coupled to the target word line WLn; the threshold voltages of the portion of the memory cells are all less than the first read voltage Vrd1.

In some implementations, referring to FIG. 13, the operating method for a memory device further includes: in the pre-pass phase, applying a fifth pass voltage Vpass5 to a second word line WLn−1 adjacent to the target word line WLn; the target word line WLn is located between the first word line WLn+1 and the second word line WLn−1; in the first sub-phase of the first read phase, reducing the voltage on the second word line WLn−1 from the fifth pass voltage Vpass5 to a fourth voltage V4; in the second sub-phase of the first read phase, increasing the voltage on the second word line WLn−1 from the fourth voltage V4 to a sixth pass voltage Vpass6.

In the implementation of the present disclosure, the operating method for the memory device includes: in a first sub-phase of each read phase for performing a read operation on a memory cell coupled to the target word line, reducing a voltage on a word line adjacent to the target word line from a pass voltage to a lower voltage; in a second sub-phase, increasing the voltage on the first word line from a lower voltage to a pass voltage; and in a third sub-phase, continuing to apply a pass voltage to the first word line, the first sub-phase and the second sub-phase may be voltage establishment phases, and the third sub-phase may be a data sensing phase, thus the time during which the voltage on the word line adjacent to the target word line is at a higher pass voltage may be shortened without affecting the data sensing operation, thereby reducing the read interference generated on the memory cells coupled to the word line adjacent to the target word line.

In an implementation of the present disclosure, an operating method for a memory device includes: sequentially applying decreasing read voltages to memory cells coupled to a target word line to read one page of data stored in the memory cells through a read operation including multiple read phases, and during the voltage drop phase on the target word line, the voltage on the word line adjacent to the target word line drops synchronously, thereby accelerating the voltage drop rate on the target word line through the coupling effect, shortening the voltage establishment phase time, and improving the efficiency of the read operation.

The features disclosed in several apparatus implementations provided in the present disclosure may be combined arbitrarily without conflicts to obtain new apparatus implementations.

The methods disclosed in several method implementations provided in the present disclosure may be combined arbitrarily without conflicts to obtain new method implementations.

The above is only specific implementations of the present disclosure, but the claimed scope of the present disclosure is not limited thereto, and changes or substitutions within the technical scope disclosed in the present disclosure that may be easily conceived by those skilled in the art shall fall within the claimed scope of the present disclosure.

What is claimed is:

1. A memory device, including:
a memory array;
a peripheral circuit coupled to the memory array;
a target word line coupled to memory cells in the memory array; and
a first word line adjacent to the target word line,
wherein the peripheral circuit is configured to:
in a pre-pass phase for performing a read operation on a memory cell coupled to the target word line, apply a first pass voltage to the first word line;
in a first sub-phase of a first read phase after the pre-pass phase, reduce the voltage on the first word line from the first pass voltage to a first voltage; and
in a second sub-phase of the first read phase, increase the voltage on the first word line from the first voltage to a second pass voltage.

2. The memory device of claim 1, wherein the peripheral circuit is further configured to:
in the pre-pass phase, apply a third pass voltage to the target word line; and
in the first read phase, apply a first read voltage to the target word line, wherein the first read voltage is less than the third pass voltage.

3. The memory device of claim 2, wherein the peripheral circuit is further configured to:
in the first sub-phase of the first read phase, reduce the voltage on the target word line from the third pass voltage to a second voltage, wherein the second voltage is less than or equal to the first read voltage.

4. The memory device of claim 2, wherein the peripheral circuit is further configured to:
in a second read phase after the first read phase for performing the read operation on the memory cell coupled to the target word line, apply a second read voltage to the target word line, wherein the second read voltage is less than the first read voltage.

5. The memory device of claim 4, wherein the peripheral circuit is further configured to:
in a first sub-phase of the second read phase, reduce the voltage on the first word line from the second pass voltage to a third voltage; and
in a second sub-phase of the second read phase, increase the voltage on the first word line from the third voltage to a fourth pass voltage.

6. The memory device of claim 5, wherein a difference between the third pass voltage and the first read voltage is greater than a difference between the first read voltage and the second read voltage.

7. The memory device of claim 6, wherein a difference between the first pass voltage and the first voltage is greater than or equal to a difference between the second pass voltage and the third voltage.

8. The memory device of claim 1, wherein the first pass voltage is equal to the second pass voltage.

9. The memory device of claim 5, wherein the peripheral circuit is further configured to:
in a third sub-phase of the first read phase, apply the second pass voltage to the first word line, and perform a first data sensing operation on the memory cells coupled to the target word line; and
in a third sub-phase of the second read phase, apply the fourth pass voltage to the first word line, and perform a second data sensing operation on a portion of the memory cells coupled to the target word line, wherein threshold voltages of the portion of the memory cells are less than the first read voltage.

10. The memory device of claim 4, wherein the memory cell coupled to the target word line is configured to store N-bit data, wherein the N is an integer greater than 2; and the peripheral circuit is configured to:
perform the read operation on the memory cell coupled to the target word line to read one bit of the N-bit data stored in the memory cell coupled to the target word line.

11. The memory device of claim 1, further including a second word line adjacent to the target word line, wherein the target word line is located between the first word line and the second word line, and the peripheral circuit is further configured to:
in the pre-pass phase, apply a fifth pass voltage to the second word line;
in the first sub-phase of the first read phase, reduce the voltage on the second word line from the fifth pass voltage to a fourth voltage; and
in the second sub-phase of the first read phase, increase the voltage on the second word line from the fourth voltage to a sixth pass voltage.

12. The memory device of claim 11, wherein the fifth pass voltage is equal to the first pass voltage, the fourth voltage is equal to the first voltage, and the sixth pass voltage is equal to the second pass voltage.

13. The memory device of claim 1, further including a third word line, wherein the first word line is located between the target word line and the third word line, and the peripheral circuit is further configured to:
when performing the read operation on the memory cell coupled to the target word line, apply a seventh pass voltage to the third word line, wherein the seventh pass voltage is less than the second pass voltage.

14. A memory system comprising:
at least one memory device that each includes:
a memory array;
a peripheral circuit coupled to the memory array;
a target word line coupled to memory cells in the memory array; and
a first word line adjacent to the target word line,
wherein the peripheral circuit is configured to:
in a pre-pass phase for performing a read operation on a memory cell coupled to the target word line, apply a first pass voltage to the first word line;
in a first sub-phase of a first read phase after the pre-pass phase, reduce the voltage on the first word line from the first pass voltage to a first voltage; and
in a second sub-phase of the first read phase, increase the voltage on the first word line from the first voltage to a second pass voltage; and
a controller coupled to the at least one memory device and configured to control the memory device.

15. An operating method for a memory device, including:
in a pre-pass phase for performing a read operation on a memory cell coupled to a target word line, applying a first pass voltage to a first word line adjacent to the target word line;
in a first sub-phase of a first read phase after the pre-pass phase, reducing the voltage on the first word line from the first pass voltage to a first voltage; and
in a second sub-phase of the first read phase, increasing the voltage on the first word line from the first voltage to a second pass voltage.

16. The operating method for a memory device of claim 15, further including:
in the pre-pass phase, applying a third pass voltage to the target word line; and
in the first read phase, applying a first read voltage to the target word line, wherein the first read voltage is less than the third pass voltage.

17. The operating method for a memory device of claim 16, wherein applying a first read voltage to the target word line in the first read phase includes:
in the first sub-phase of the first read phase, reducing the voltage on the target word line from the third pass voltage to a second voltage, wherein the second voltage is less than or equal to the first read voltage.

18. The operating method for a memory device of claim 16, further including:
in a second read phase after the first read phase for performing the read operation on the memory cell coupled to the target word line, applying a second read voltage to the target word line, wherein the second read voltage is less than the first read voltage.

19. The operating method for a memory device of claim 18, further including:
in a first sub-phase of the second read phase, reducing the voltage on the first word line from the second pass voltage to a third voltage; and
in a second sub-phase of the second read phase, increasing the voltage on the first word line from the third voltage to a fourth pass voltage.

20. The operating method for a memory device of claim 19, wherein a difference between the third pass voltage and the first read voltage is greater than a difference between the first read voltage and the second read voltage.
